(19) United States
(12) Patent Application Publication
(10) Pub. No.: US 2016/0099183 A1
(43) Pub. Date: Apr. 7, 2016

(54) METHOD FOR RELAXING THE TRANSVERSE MECHANICAL STRESSES WITHIN THE ACTIVE REGION OF A MOS TRANSISTOR, AND CORRESPONDING INTEGRATED CIRCUIT

(71) Applicants: STMicroelectronics (Crolles 2) SAS, Crolles (FR); STMicroelectronics SA, Montrouge (FR); Commissariat A L'Energie Atomique et aux Energies Alternatives, Paris (FR)

(72) Inventors: Denis Rideau, Grenoble (FR); Elise Baylac, Les Adrets (FR); Emmanuel Richard, Saint Pierre D'allevard (FR); Francois Andrieu, Saint-Ismier (FR)

(73) Assignees: STMicroelectronics (Crolles 2) SAS, Crolles (FR); STMicroelectronics SA, Montrouge (FR); Commissariat A L'Energie Atomique et aux Energies Alternatives, Paris (FR)

(21) Appl. No.: 14/965,990

(22) Filed: Dec. 11, 2015

Related U.S. Application Data
(62) Division of application No. 14/505,570, filed on Oct. 3, 2014.

(30) Foreign Application Priority Data
Oct. 7, 2013 (FR) 1359703

(51) Int. Cl. H01L 21/84; H01L 21/8234; H01L 21/762; H01L 29/10

(52) U.S. Cl. CPC H01L 21/84; H01L 29/1033; H01L 21/823412; H01L 21/823481; H01L 21/76283

(57) ABSTRACT

The transverse mechanical stress within the active region of a MOS transistor is relaxed by forming an insulating incursion, such as an insulated trench, within the active region of the MOS transistor. The insulated incursion is provided at least in a channel region of the MOS transistor so as to separate the channel region into two parts. The insulated incursion is configured to extend in a direction of a length of the MOS transistor. The insulated incursion may further extend into one or more of a source region or drain region located adjacent the channel region of the MOS transistor.

### CROSS-REFERENCE TO RELATED APPLICATIONS

This application is a divisional application from U.S. patent application Ser. No. 14/505,570 filed Oct. 3, 2014, which claims priority from French Application for U.S. Pat. No. 1,359,703 filed Oct. 7, 2013, the disclosures of which are incorporated by reference.

### TECHNICAL FIELD

The invention relates to integrated circuits and, more particularly, the transverse mechanical stresses within the active region of an MOS transistor, in other words the stresses in the direction of the width of the active region (the length of the gate of a transistor being the source-drain distance of the transistor).

### BACKGROUND

The active regions of the transistors which incorporate the source, drain and channel regions, may be subjected to transverse mechanical stresses which are detrimental to the operation of the transistors and reduce their performance.

This reduction in performance is notably observed on wide transistors, of the PMOS type, or else on the transistors formed on a substrate comprising silicon and germanium.

The width of a transistor means the dimension of the transistor counted in a direction transverse to the direction in which the charge carriers are moving.

A drop in the intensity of the current of several tens of percent may for example be observed for ratios of length over width which approach 0.2.

### SUMMARY

According to one embodiment and its implementation, the idea is to relax the transverse mechanical stresses within the active region of a MOS transistor in a manner that is simple to implement.

According to one aspect, a method is provided for relaxing, in other words releasing, transverse mechanical stresses within the active region of a MOS transistor. The method according to this aspect comprises the formation of at least one insulating incursion, for example made of silicon dioxide, into at least the channel region of the transistor, running in the direction of the length of the channel region and separating at least the channel region into two parts in the direction of its width.

The length of the channel region is the drain-source distance. The width of the channel region is the dimension perpendicular to the length.

It is observed that, by forming at least one insulating incursion, for example made of silicon dioxide, into at least the channel region of a transistor, for example an incursion which runs in the same direction as the direction of travel of the charge carriers through the transistor (the direction of the channel), an increase in the mobility of the charge carriers that can be as high as +57% (depending on the total width of the transistor) with respect to a transistor without incursion is obtained.

Such an insulating incursion may also be called “relaxing” incursion since, even when it is formed only in the channel region, it allows the stresses within the active region of the transistor to be relaxed.

A plurality of incursions may also be formed in order to obtain a better relaxation of the transverse stresses, for example by forming n insulating incursions in at least the channel region of the transistor, running in the direction of the length of the channel region and separating at least the channel region into n+1 parts in the direction of its width.

Each incursion may also partially separate each of the drain and source regions of the transistor in the direction of their width, thus leaving continuous portions of drain and source regions remaining.

This is especially applicable in the case of a substrate of the silicon-on-insulator (SOI) type, for which, if the incursion or incursions extend as far as the buried insulating layer (BOX), they must not extend over the entire length of the source and drain regions. If, on the other hand, they extend over the entire length of the source and drain regions, they must not extend as far as the buried insulating layer.

Forming incursions also into the source and drain regions allows a better relaxation to be obtained since the transverse mechanical stresses are relaxed over a wider area.

Incursions having various widths may be formed. However, it is preferable to reduce the surface occupied by the transistors, while at the same time forming incursions sufficiently wide to obtain a relaxation of the stresses. By way of example, each incursion may be formed with a width in the range between 10 and 20 nanometers.

The width of each part of each of the drain, source and/or channel regions of the transistor can be adjusted in order to obtain a good relaxation. Indeed, if this width is too large, transverse stresses may again be seen to appear. By way of example, the width of each of the said parts can be in the range between 50 and 120 nanometers. This width corresponds to the space between two incursions.

The transistor may be formed with a large total width, for example greater than 120 nanometers or even greater than 500 nanometers. It is indeed advantageous to relax the transverse stresses within such wide transistors.

Each incursion can comprise a shallow insulating trench. Thus, the incursions may be implemented simultaneously with the formation of the shallow insulating trenches formed around the active regions of the transistors in order to provide a lateral insulation.

The transistor can be formed on a substrate of the silicon-on-insulator (SOI) type, for example of the type fully-depleted silicon-on-insulator (FDSOI). Such a substrate comprises a silicon film separated from a carrier substrate by a buried insulating layer (commonly denoted by those skilled in the art under the acronym “BOX”), and each incursion can be formed in the silicon film.

Each incursion can partially extend into the thickness of the silicon film without reaching the buried insulating layer.

According to another aspect, an integrated circuit comprising at least one MOS transistor is provided.

The integrated circuit according to this aspect comprises, at least within its channel region, at least one insulating incursion running in the direction of the length of the channel region and separating at least the channel region into two parts in the direction of its width.

The integrated circuit can comprise n incursions in at least the channel region of the transistor, running in the direction of the width of the channel region and separating at least the channel region into n+1 parts in the direction of its width.

Each incursion may also partially separate each of the drain and source regions of the transistor into several parts in the direction of their width, leaving continuous source and drain regions remaining.

Each incursion can have a width in the range between 10 and 20 nanometers.

The width of each of the said parts can be in the range between 50 and 120 nanometers.

The transistor can have a total width greater than 120 nanometers or even greater than 500 nanometers.

Each incursion can comprise a shallow insulating trench.

The transistor can be situated on a substrate of the silicon-on-insulator type comprising a silicon film separated from a carrier substrate by a buried insulating layer, and each incursion is advantageously situated in the silicon film.

Each incursion can be situated within the silicon film without reaching the buried insulating layer. The height of each incursion situated within the silicon film can be less than the thickness of the silicon film.

### BRIEF DESCRIPTION OF THE DRAWINGS

Other advantages and features of the invention will become apparent upon studying the detailed description of embodiments and their implementation, taken by way of non-limiting examples and illustrated by the appended drawings in which:

FIG. 1 is a top view of a transistor according to one embodiment,

FIG. 2 is a cross-sectional view of a transistor according to one embodiment,

FIG. 3 is a cross-sectional view of a transistor according to another embodiment, and

FIG. 4 is a top view of a transistor according to yet another embodiment.

### DETAILED DESCRIPTION OF THE DRAWINGS

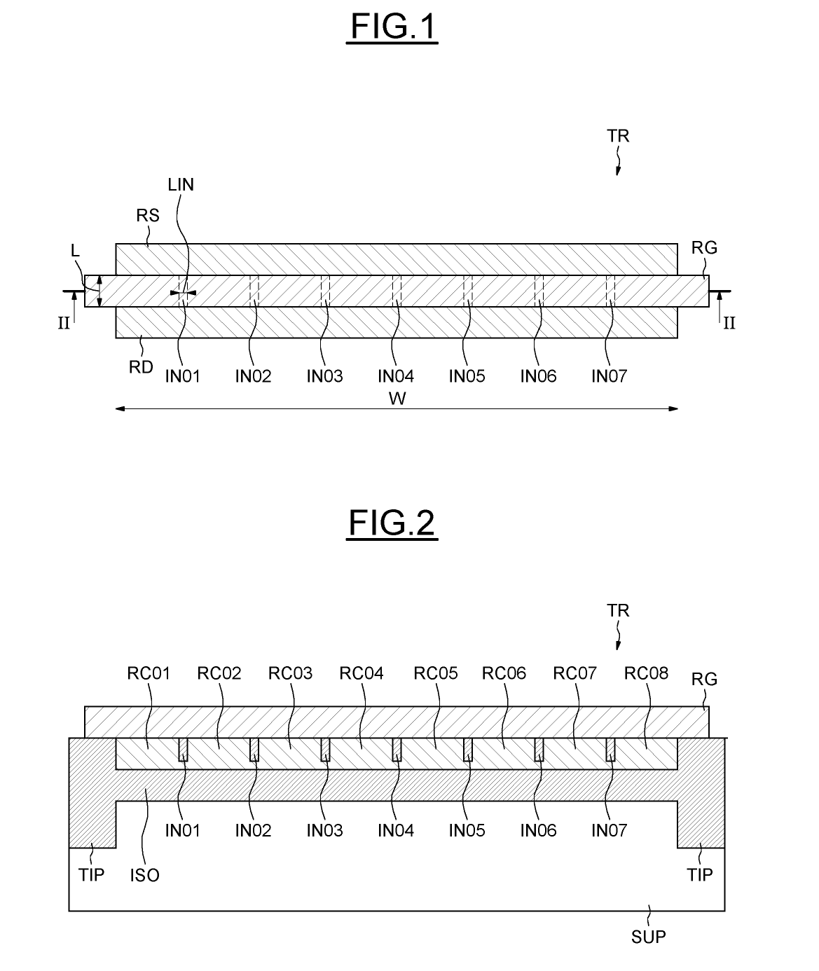

FIG. 1 shows schematically a top view of an MOS transistor TR, comprising a gate region RG, which runs in the direction of the width W of the transistor TR, a drain region RD and a source region RS. The width W of the transistor is the width W of its channel region and the length L of the gate is the length of the channel.

Prior to the formation of the gate region RG, in order to relax the transverse mechanical stresses, several incursions IN01, IN02, IN03, IN04, IN05, IN06, IN07 have been formed in a region of the substrate destined to become the channel region of the transistor TR.

These incursions have a width LIN chosen for example so as to sufficiently relax the transverse mechanical stresses, and also chosen so as not to overly increase the surface area occupied by the transistor TR.

The incursions IN01 to IN07 can be shallow insulating trenches. In other words, they can be formed, in a conventional manner known per se, simultaneously with the formation of the shallow insulating trenches that laterally insulate the active regions of the transistors.

Alternatively, incursions may be formed during specific steps which are not common to those for fabrication of the shallow insulating trenches. Trenches with a shallower depth can thus be formed.

In the embodiment in FIG. 1 and in FIG. 2, the incursions only extend through the channel region; transistors according to methods well known to those skilled in the art by the expression “gate-last” may thus be formed.

FIG. 2 shows a cross-sectional view of the transistor TR along the line II-II in FIG. 1.

The incursions number seven, therefore eight channel region parts RC01, RC02, RC03, RC04, RC05, RC06, RC07 and RC08 are obtained.

Although not essential, it is possible to form the transistor TR on a support of the silicon-on-insulator type comprising a carrier substrate SUP, a buried insulating layer ISO, and a silicon film in which the incursions IN01 to IN07 are formed.

Furthermore, deep insulating trenches TIP are disposed on either side of the transistor TR. These trenches pass through the buried insulating layer ISO and extend into the carrier substrate SUP.

It can be noted that, in the variant illustrated in FIG. 2, the incursions IN01 to IN07 only extend through the channel region and into the silicon film without reaching the buried insulating layer ISO.

It can be noted that a relaxation effect on the stresses is obtained even with very shallow incursions.

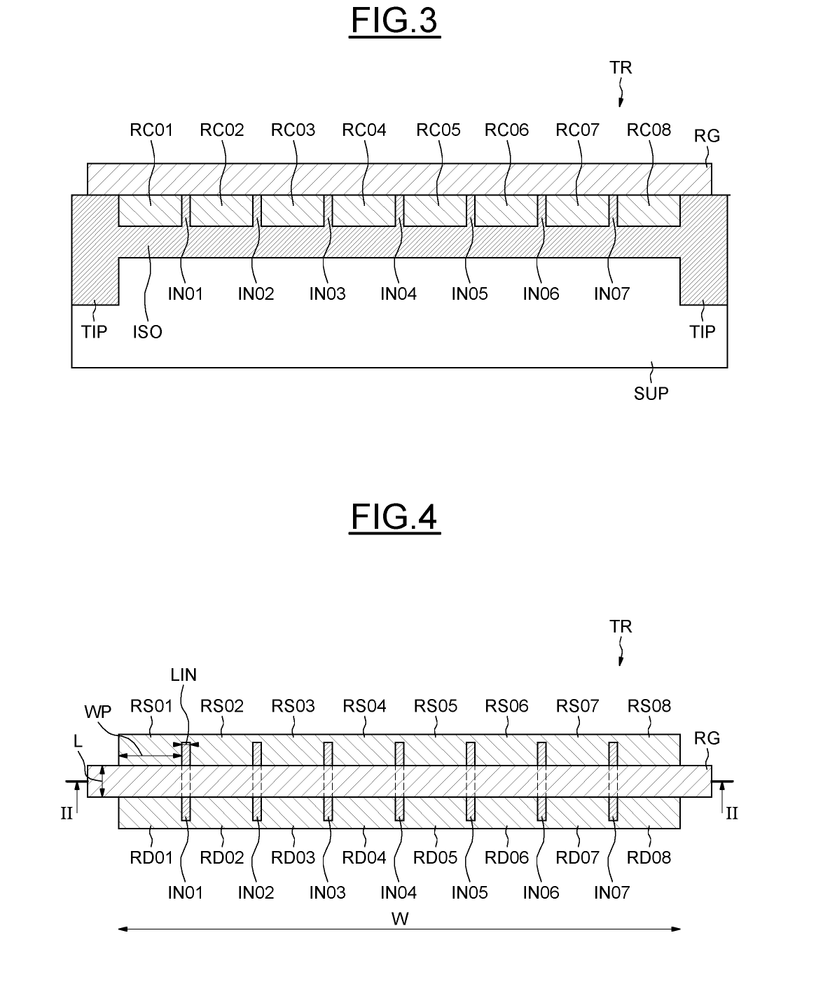

Other depths of incursion are possible. In particular, it is possible to form incursions which extend as far as the buried insulating layer ISO, as illustrated on the variant embodiment in FIG. 3 which is a cross-sectional view going through the gate region RG of the transistor TR.

Lastly, as illustrated in FIG. 4, the incursions may, as a variant, extend beyond the channel region of the transistor TR.

By extending into the source and drain regions, eight drain parts RD01, RD02, RD03, RD04, RD05, RD06, RD07 and RD08 are obtained, together with eight source parts RS01, RS02, RS03, RS04, RS05, RS06, RS07 and RS08.

The incursions IN01 to IN07 only partially separate the drain parts RD01 to RD08, and they only partially separate the source parts RS01 to RS08. Indeed, the incursions IN01 to IN07 do not run over the entire length of the drain and source regions. Thus, in particular, in SOI technology, continuous portions of source and drain regions are obtained for the same transistor, even though the incursions can extend as far as the buried insulating layer. For incursions which do not extend as far as the buried insulating layer, it is possible to form incursions which run over the whole length of the source and drain regions, which then form continuous portions of source and drain under the incursions.

It can be observed that, without the incursions IN01 to IN07, the total width of the transistor would be increased. By way of example, for a width of incursion LIN of around 20 nanometers, and for a width of the portion WP of around 80 nanometers, a loss of width of around 20% is obtained. However, it should be noted that the mobility of the charge carriers is sufficiently improved by the relaxation of the mechanical stresses so as to compensate for this reduction in width.

According to one aspect, a relaxation of the transverse mechanical stresses is obtained.

This relaxation allows an improvement in the mobility of the charge carriers to be obtained which compensates for any loss of width of transistor.

Furthermore, according to another aspect, the invention can be implemented without the need for an additional fabrication step, notably by using shallow insulating trenches.

The invention is applicable to any type of technology (bulk substrate, silicon-on-insulator (SOI), fully-depleted silicon-on-insulator (FDSOI) or partially-depleted SOI (PDSOI)).

What is claimed is:

1. A method for relaxing transverse mechanical stresses within an active region of a MOS transistor, comprising:
forming at least one trench in at least a channel region of the MOS transistor, said channel region provided in a substrate of a silicon-on-insulator type comprising a silicon film separated from a carrier substrate by a buried insulating layer;
wherein the at least one trench is formed in the silicon film;
wherein said at least one trench extends in a direction of a length of the channel region and separates at least the channel region into two parts in a direction of a width of the channel region; and
filling the at least one trench with an insulating material to form an insulating incursion extending under a gate electrode of said MOS transistor.

2. The method according to claim 1, wherein forming at least one trench comprises forming a plurality of trenches in at least the channel region of the transistor, wherein filling comprises filling each trench with insulating material to form a corresponding insulating incursion extending in the direction of the length of the channel region and separating at least the channel region into a plurality of parts in the direction of the width.

3. The method according to claim 1, wherein forming at least one trench comprises forming said at least one trench to extend into at least one of a drain region or a source region of the transistor adjacent the channel region.

4. The method according to claim 1, wherein said at least one trench has a width in a range between 10 and 20 nanometers.

5. The method according to claim 1, wherein a width of parts of the channel region on each side of the trench is in a range between 50 and 120 nanometers.

6. The method according to claim 1, wherein a total width of the channel region is greater than 120 nanometers.

7. The method according to claim 1, wherein a total width of the channel region is greater than 500 nanometers.

8. The method according to claim 1, further comprising forming a shallow insulating trench.

9. The method according to claim 8, wherein forming said trench is performed simultaneously with forming said shallow insulating trench.

10. The method according to claim 1, wherein forming said at least one trench comprises forming said at least one trench with a depth that partially extends into a thickness of the silicon film without reaching the buried insulating layer.

11. The method according to claim 1, wherein forming said at least one trench comprises forming said at least one trench with a depth that extends completely through a thickness of the silicon film and reaches the buried insulating layer.

12. The method according to claim 1, wherein forming said at least one trench comprises performing an etch to form the trench with sidewalls that are substantially perpendicular to a top surface of the silicon film.

13. The method according to claim 12, wherein filling the at least one trench with the insulating material comprises filling with the insulating material to a level coplanar with the top surface of the silicon film.

14. A method for relaxing transverse mechanical stresses within an active region of a MOS transistor, comprising:
etching a trench in at least a channel region of the MOS transistor, said channel region provided in a substrate of a silicon-on-insulator type comprising a silicon film separated from a carrier substrate by a buried insulating layer;
wherein the trench is formed in the silicon film;
wherein said at least one trench extends in a direction of a length of the channel region and separates at least the channel region into two parts in a direction of a width of the channel region; and
filling the trench with an insulating material to form an insulating incursion extending under a gate electrode of said MOS transistor.

15. The method according to claim 14, wherein etching comprises forming said trench with sidewalls that are substantially perpendicular to a top surface of the silicon film.

16. The method according to claim 15, wherein filling the trench with the insulating material comprises filling with the insulating material to a level coplanar with the top surface of the silicon film.

17. The method according to claim 14, wherein etching the trench comprises forming the trench to extend into at least one of a drain region or a source region of the transistor adjacent the channel region.

18. The method according to claim 14, further comprising forming a shallow insulating trench, wherein etching said trench comprises etching a further trench for said shallow insulating trench.

19. The method according to claim 14, wherein etching said trench comprises forming said with a depth that partially extends into a thickness of the silicon film without reaching the buried insulating layer.

20. The method according to claim 14, wherein etching said trench comprises forming said at least one trench with a depth that extends completely through a thickness of the silicon film and reaches the buried insulating layer.
